(19) United States
(12) Patent Application Publication
(10) Pub. No.: US 2008/0284048 A1
(43) Pub. Date: Nov. 20, 2008

(54) Alignment mark, semiconductor chip including the same, semiconductor package including the chip and methods of fabricating the same

(75) Inventors: Sung-jae Kim, Seongnam-si (KR); Yong-bok Park, Yongin-si (KR); Jung-soo Nam, Seoul (KR); In-jung Lee, Yongin-si (KR); Sung-jun Kim, Incheon (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/153,088

(22) Filed: May 14, 2008

(30) Foreign Application Priority Data
May 14, 2007 (KR) 10-2007-0046768

(51) Int. Cl. H01L 23/544; H01L 21/50

(52) U.S. Cl. 257/797; 438/401; 257/E23.179; 257/E21.499

(57) ABSTRACT

Provided are an alignment mark with a higher rate of recognition, a semiconductor chip including the alignment mark, a semiconductor package including the semiconductor chip, and methods of fabricating the alignment mark, the semiconductor chip, and the semiconductor package. The alignment mark may include an align metal pad on a substrate and may be electrically isolated. A protective film may be on the align metal pad and may include an aperture exposing a part of the align metal pad. A metal alignment bump may be on the align metal pad exposed in the aperture such that the metal alignment bump protrudes above the protective film.

### PRIORITY STATEMENT

This application claims the benefit under 35 U.S.C. §119 of Korean Patent Application No. 10-2007-0046768, filed on May 14, 2007, in the Korean Intellectual Property Office, the entire contents of which are incorporated herein by reference.

### BACKGROUND

1. Field

Example embodiments relate to an alignment mark with an improved rate of recognition, a semiconductor chip including the alignment mark, a semiconductor package including the semiconductor chip, and methods of fabricating the alignment mark, the semiconductor chip, and the semiconductor package.

2. Description of the Related Art

Generally semiconductor packages are fabricated by mounting a semiconductor chip on a wiring substrate. In order to align the bonding pad of the wiring substrate and the terminal pad of the semiconductor chip, an alignment mark is formed within the semiconductor chip. If the alignment mark is formed faintly so as to have a poor rate of recognition, the bonding pad and the terminal pad may be misaligned, and thus may not have a good electrical connection.

### SUMMARY

Example embodiments provide an alignment mark with higher rate of recognition, a semiconductor chip including the alignment mark, a semiconductor package including the semiconductor chip, and methods of fabricating the alignment mark, the semiconductor chip, and the semiconductor package.

Example embodiments may include an alignment mark comprising an align metal pad, a protective film, and/or at least a portion of a metal alignment bump. The align metal pad may be on a substrate. The align metal pad may be electrically isolated. The alignment mark may include a protective film including a first aperture exposing a part of the align metal pad. The alignment mark may also include an metal alignment bump on the align metal pad exposed in the first aperture and protruding above the protective film. The metal alignment bump may be used to align the substrate to an exterior substrate.

According to at least some example embodiments, the metal alignment bump may extend over the protective film. A seed metal layer may be between the align metal pad and the metal alignment bump.

Example embodiments may include a semiconductor chip including an alignment mark. The substrate may further include an alignment mark region and a terminal pad region.

According to at least some example embodiments, the semiconductor chip may include an align metal pad on the alignment mark region and a chip metal pad on the terminal pad region. According to at least some example embodiments, the protective film may include a first aperture and the metal alignment bump and a second aperture exposing a portion of the chip metal pad.

According to at least some example embodiments, a chip metal bump may be on a chip metal pad exposed in the second aperture. The chip metal bump may protrude above the protective film.

Example embodiments may include a semiconductor package comprising a semiconductor chip. At least some example embodiments may provide a wiring substrate including a bonding pad for mounting the semiconductor chip. The bonding pad and the chip metal pad may be electrically connected to each other.

According to at least some example embodiments, the semiconductor package may further include a display unit that is electrically connected with the bonding pad and on the wiring substrate.

Example embodiments may include a method of fabricating an alignment mark, the method comprising providing an align metal pad on a substrate, and providing a protective film including a first aperture exposing a part of the align metal pad. An metal alignment bump may be formed on the align metal pad exposed in the first aperture and protruding above the protective film.

Example embodiments may include a method of fabricating a semiconductor chip. The method may include fabricating an alignment mark. The substrate may include an alignment mark region and a terminal pad region. According to at least some example embodiments, the align metal pad and the metal alignment bump may be formed in the alignment mark region, and a chip metal pad may be formed in the terminal pad region. Example embodiments may also provide forming a second aperture in the protective film exposing a part of the chip metal pad.

At least some example embodiments may provide a method of forming a chip metal bump, simultaneous to forming the metal alignment bump, on the chip metal pad exposed in the second aperture to protrude above the protective film.

At least some example embodiments may provide a method of forming a seed metal layer, before forming the metal alignment bump and the chip metal bump, on the align metal pad exposed in the first aperture and on the chip metal pad exposed in the second aperture.

According to example embodiments, the metal alignment bump and the chip metal bump may be formed using electroplating. The metal alignment bump may be formed to extend over the protective film.

Example embodiments may include a method of fabricating a semiconductor package. The method may include forming a semiconductor chip. The method may further include providing a wiring substrate and a bonding pad for mounting the semiconductor chip. According to at least some example embodiments, the method may include aligning the semiconductor chip to the wiring substrate using the metal alignment bump as an alignment mark. The method may further include electrically connecting the bonding pad and the chip metal pad.

According to example embodiments, the wiring substrate may include a display unit that is electrically connected to the bonding pad.

According to at least some example embodiments, the semiconductor chip may further include a chip metal bump disposed on the chip metal pad exposed in the second aperture and protruding above the protective film. The semiconductor chip may be aligned such that the chip metal bump on the wiring substrate faces the bonding pad. The bonding pad and the chip metal pad may be electrically connected to each other through the chip metal bump.

### BRIEF DESCRIPTION OF THE DRAWINGS

The above and other features and advantages of example embodiments will become more apparent by describing in detail the attached drawings in which:

FIG. 1 is an example top view of a semiconductor chip according to example embodiments;

FIGS. 2A to 2D are example cross-sectional views for describing a method of forming an alignment mark according to example embodiments, taken along lines I-I and II-II of FIG. 1 according to each stage of the process;

FIG. 3 is an example cross-sectional view for describing a method of forming an alignment mark according to example embodiments, taken along lines I-I and II-II of FIG. 1;

FIGS. 4A and 4B are example top views for describing a method of fabricating a semiconductor package according to example embodiments; and

FIG. 5A is an example cross-sectional view taken along lines 111-111 and IV-IV of FIG. 4A, and FIG. 5B is an example cross-sectional view taken along lines III-III and IV-IV of FIG. 4B.

### DETAILED DESCRIPTION

Various example embodiments will now be described more fully with reference to the accompanying drawings. However, specific structural and functional details disclosed herein are merely representative for purposes of describing example embodiments, and one skilled in the art will appreciate that example embodiments may be embodied in many alternate forms and should not be construed as limited to only the example embodiments set forth herein.

It should be understood that, although the terms first, second, etc. may be used herein to describe various elements, these elements should not be limited by these terms. These terms are only used to distinguish one element from another. For example, a first element could be termed a second element, and similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a similar fashion (e.g., “between” versus “directly between”, “adjacent” versus “directly adjacent”, etc.).

The terminology used herein is for the purpose of describing example embodiments only and is not intended to be limiting of the example embodiments. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Example embodiments described below with respect to the drawings are provided so that this disclosure will be thorough, complete and fully convey the concept of example embodiments to those skilled in the art. In the drawings, like numbers refer to like elements throughout. Further, the thicknesses of layers and regions are exaggerated for clarity in the drawings.

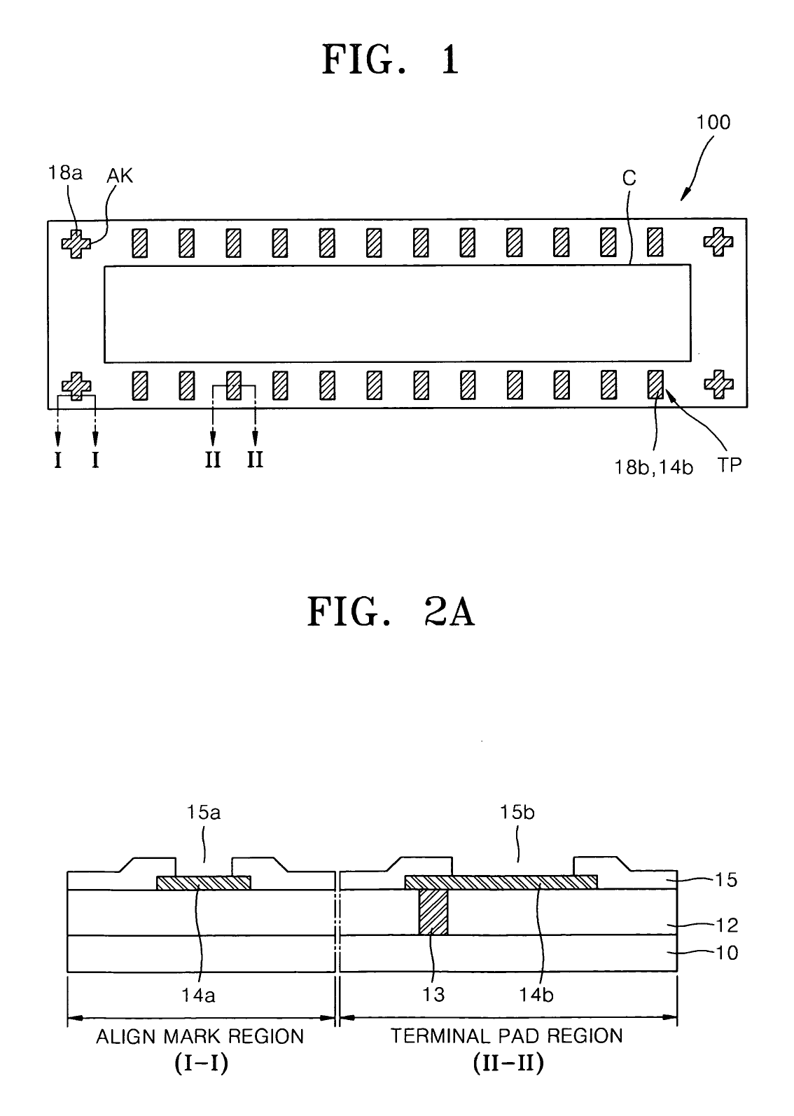

Referring to FIG. 1, a semiconductor chip 100 may include a main circuit region C. Example embodiments where the semiconductor chip 100 is a memory semiconductor chip, the main circuit region C may be a memory cell array region, or alternately, example embodiments where the semiconductor chip 100 is a non-memory semiconductor chip, the main circuit region C may be an operational circuit region. In example embodiments where the semiconductor chip 100 is a display driving IC, which is a type of a non-memory semiconductor chip, the operational circuit region, as the main circuit region C, may include a graphic controller, a timing controller, a level shifter, a common voltage generator, a data driver, and/or a gate driver or the like.

Terminal pads TP may be located outside of the main circuit region C. Terminal pads TP may input electrical signals to the main circuit region C and output electrical signals from the main circuit region C, and alignment marks AK may align the terminal pads TP on the bonding pads of the wiring substrate. The alignment marks AK may be disposed on the top, bottom, left, right, and/or corners of the semiconductor chip 100. However, the positions of the main circuit region C, the terminal pads TP, and the alignment marks AK are not limited thereto.

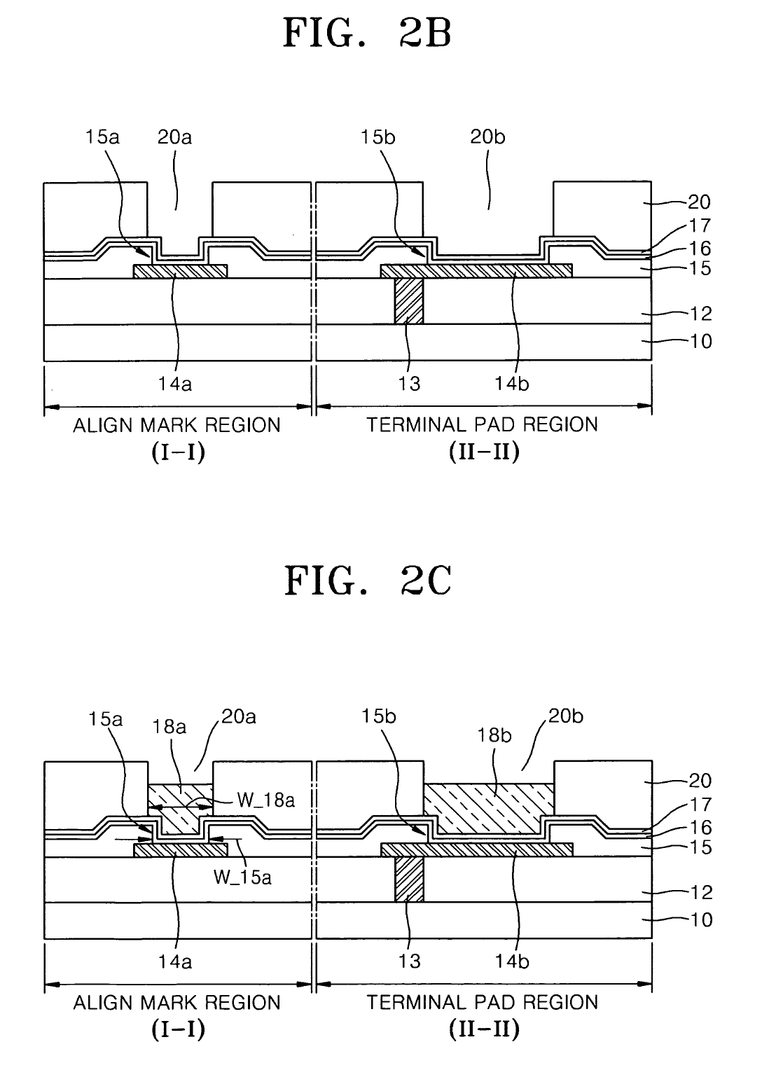

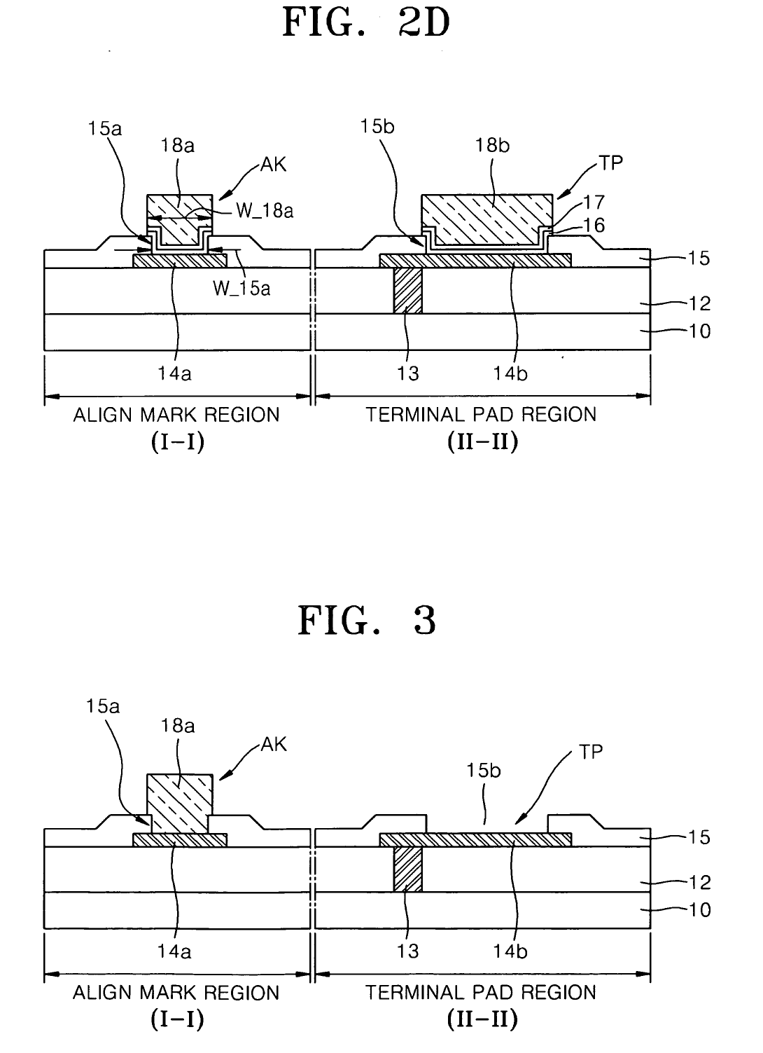

FIG. 2D is a cross-sectional view illustrating the alignment marks AK, according to example embodiments, taken along lines I-I and II-II of FIG. 1.

Referring to FIGS. 1 and 2D, an align metal pad 14a may be arranged on an alignment mark region of a substrate 10 and a chip metal pad 14b may be arranged on a terminal pad region of the substrate 10. The align metal pad 14a and the chip metal pad 14b may be formed on an insulating film 12, which may also be formed on the substrate 10. The align metal pad 14a and the chip metal pad 14b may be formed with the same metal film, such as an Al film, or a Cu film.

While the chip metal pad 14b may be electrically connected to the main circuit region C, the align metal pad 14a may be electrically isolated. For example, the chip metal pad 14b may be connected to a plug electrode 13 that is electrically connected to the main circuit region C, and disposed in the insulating film 12.

A protective film 15 including a first aperture 15a exposing a part of the align metal pad 14a and a second aperture 15b exposing a part of the chip metal pad 14b may be arranged on the align metal pad 14a and the chip metal pad 14b. The protective film 15 may be a silicon nitride film, silicon oxide film, silicon oxynitride, or a multilayer thereof. An organic polymer layer (not shown) may be further disposed on the protective layer 15.

An metal alignment bump 18a may be provided on the align metal pad 14a exposed in the first aperture 15a. The metal alignment bump 18a may protrude above the protective film 15, and may function as an alignment mark AK. For example, the portion of the metal alignment bump 18a protruding from the protective film 15 functions as the alignment mark AK. In example embodiments, the relatively large level of reflection of the metal alignment bump 18a may increase the contrast between the metal alignment bump 18a and the protective film 15, thereby improving the rate of recognition of the alignment mark AK when using alignment equipment. Additionally, due to its relatively large level of reflection, the metal alignment bump 18a may be capable of achieving stable contrast, even when the thickness of the metal alignment bump 18a varies.

A chip metal bump 18b may be disposed on the chip metal pad 14b exposed in the second aperture. The chip metal bump 18b may protrude above the protective film 15. The metal alignment bump 18a and the chip metal bump 18b may be films of the same metal, for example, films such as an Al film, a Ni film, a Pd film, a Ag film, a Au film, or a multilayer thereof. Moreover, the metal alignment bump 18a and the chip metal bump 18b may have the same height.

A seed metal layer 17 may be arranged between the metal alignment bump 18a and the align metal pad 14a, and between the chip metal bump 18b and the chip metal pad 14b. The seed metal layer 17, in example embodiments where the metal alignment bump 18a is formed using electroplating, may be a layer functioning as a seed, which may be Cu, Ni, NiV, TiW, Au, Al, or a multi metal layer thereof. A seed metal adhesion layer 16 may be interposed between the seed metal layer 17 and the align metal pad 14a, and between the seed metal layer 17 and the chip metal pad 14b. The seed metal adhesion layer 16 may improve an adhesion force between the align metal and chip pads 14a and 14b and the seed metal layer 17. The seed metal adhesion layer 16 may be formed of Ti, TiN, Cr, al, Ni, Pd, or a multi metal layer thereof. However, in example embodiments where the align metal and chip metal bumps 18a and 18b are not formed by electroplating, forming the seed metal layer 17 and the seed metal adhesion layer 16 may be omitted. Even in this example embodiment, both the metal alignment bump 18a and the align metal pad 14a are metals, therefore the adhesion force therebetween is stronger, so that the metal alignment bump 18a may not be dislocated from the substrate 10 during shipping and/or packaging of the semiconductor chip 100. Such an adhesion force between the metal alignment bump 18a and the align metal pad 14a may be further enhanced if the seed metal layer 17 and the seed metal adhesive layer 16 are formed.

An upper width W_18a of the metal alignment bump 18a may be the same or larger than a width W_15a of the first aperture 15a. In example embodiments, the upper width W_18a of the metal alignment bump 18a may be larger than the width W_15a of the first aperture 15a. In this example embodiment, the metal alignment bump 18a may be extended over the protective film 15. Therefore, the metal alignment bump 18a may be arranged on the protective film 15, and may thus stably achieve the contrast between the metal alignment bump 18a and the protective film 15 at all sidewalls of the metal alignment bump 18a.

FIGS. 2A to 2D are cross-sectional views for describing a method of forming an alignment mark AK according to example embodiments, taken along lines I-I and II-II of FIG. 1 according to each stage of the process.

Referring to FIG. 2A, a semiconductor substrate 10 may include an alignment mark region and a terminal pad region. An insulating film 12 may be formed on the semiconductor substrate 10. A plug electrode 13 that is electrically connected to the main circuit region C of FIG. 1 may be formed in the insulating film 12. A first metal film is formed on the insulating film 12, and the first metal film may be patterned to form an align metal pad 14a and a chip metal pad 14b connected to the plug electrode 13, each on the alignment mark region and the terminal pad region, respectively. The first metal film may be an Al film or a Cu film.

A protective film 15 may be formed on the align metal pad 14a and the chip metal pad 14b. An organic polymer layer may further be formed on the protective film 15 (not shown). The protective film 15 and the organic polymer layer may be patterned to form a first aperture 15a exposing a part of the align metal pad 14a and to form a second aperture 15b exposing a part of the chip metal pad 14b.

Referring to FIG. 2B, a seed metal layer 17 may be formed on the protective film 15; and the align metal pad 14a and the chip metal pad 14b may be exposed in the first and the second apertures 15a and 15b, respectively. Before forming the seed metal layer 17, a seed metal adhesive layer 16 may be formed on the protective film 15. The seed metal adhesive layer 16 and the seed metal layer 17 may be formed consecutively using sputtering.

A mask pattern 20 may be formed on the seed metal layer 17. The mask pattern 20 may include a third aperture 20a and a fourth aperture 20b exposing the seed metal layer 17 formed in the first aperture 15a and the second aperture 15b, respectively. The third aperture 20a and the fourth aperture 20b may be formed so as to have at least the same width as the first and the second apertures 15a and 15b, but may be formed so as to have a larger width than those of the first and the second apertures 15a and 15b. As a result, the seed metal layer 17 may be formed on the protective film 15 adjacent to the first and the second apertures 15a and 15b may be exposed in the third and the fourth apertures 20a and 20b. The mask pattern 20 may be a photoresist pattern.

Referring to FIG. 2C, a second metal film may be formed on the seed metal layer 17 exposed in the third and the fourth apertures 20a and 20b. As a result, an metal alignment bump 18a and a chip metal bump 18b may be formed on the align metal pad 14a and the chip metal pad 14b, respectively. In example embodiments where the width of the third aperture 20a is formed to be larger than the width of the first aperture 15a, the upper width W_18a of the metal alignment bump 18a may be larger than the width W_15a of the first aperture 15a, and the metal alignment bump 18a may be extended over the protective film 15.

The second metal film may be formed using electroplating method. In example embodiments, the seed metal layer 17 may be used as a leading wire for seeding or plating. However, in example embodiments where the second metal film is formed using a method other than electroplating, for example, by electroless plating, metal film deposition and etching, or printing, forming of the seed metal layer 17 and the seed metal adhesive layer 16 may be omitted. In this case, the metal alignment bump 18a and the align metal pad 14a may be formed so as to be in contact with each other, and the chip metal bump 18b and the chip metal pad 14b may be formed so as to be in contact with each other.

Referring to FIG. 2D, the mask pattern 20 may be removed so as to expose the seed metal layer 17. Using the bumps 18a and 18b as a mask, the seed metal layer 17 and the seed metal adhesive layer 16 that are exposed may be etched. As a result, a terminal pad TP of which the chip metal pad 14b, the seed metal adhesive layer 16, the seed metal layer 17, and the chip metal bump 18b may be stacked in order on the terminal pad region is formed. Moreover, the portion of the metal alignment bump 18a protruding from the protective film 15 may function as the alignment mark AK.

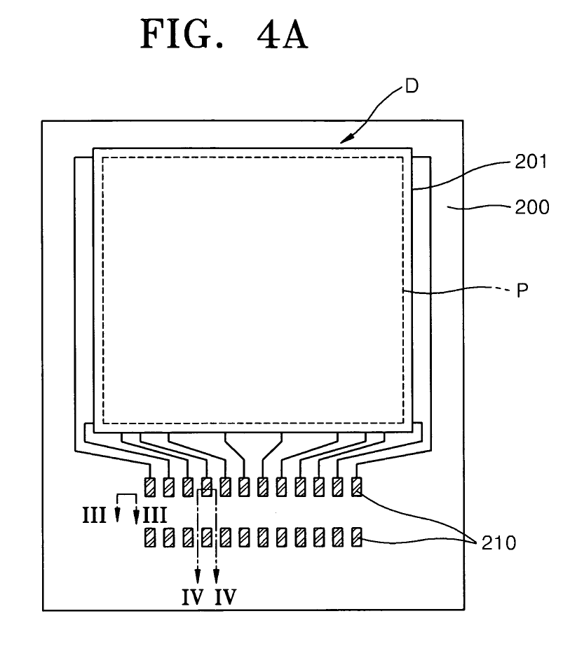

FIG. 3 is an example cross-sectional view for describing a method of forming an alignment mark AK, according to example embodiments, taken along lines I-I and II-II of FIG. 1.

Referring to FIG. 3, a protective film 15 including a wire 11, an insulating film 12, a plug electrode 13, an align metal pad 14a, a chip metal pad 14b, and a first aperture 15a and a second aperture 15b may be formed on a semiconductive substrate 10 including an alignment mark region and a terminal pad region, using the same method as described with reference to FIG. 2A.

An metal alignment bump 18a may be formed on an align metal pad 14a exposed in the first aperture 15a. The metal alignment bump 18a may be formed using electroplating, electroless plating, metal film deposition and etching, or printing. The chip metal pad 14b may be directly exposed in the second aperture 15b. The chip metal pad 14b exposed in the second aperture 15b may function as a terminal pad TP, and the portion of the metal alignment bump 18a protruding from the protective film 15 may function as the alignment mark AK.

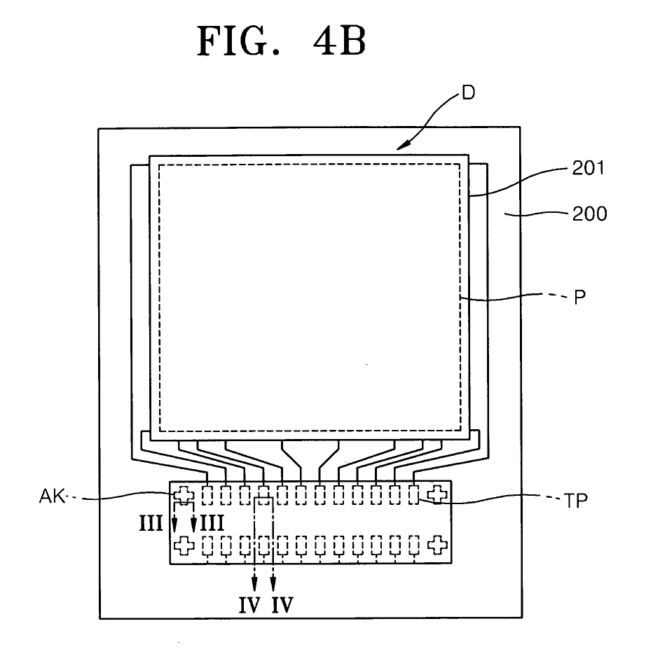

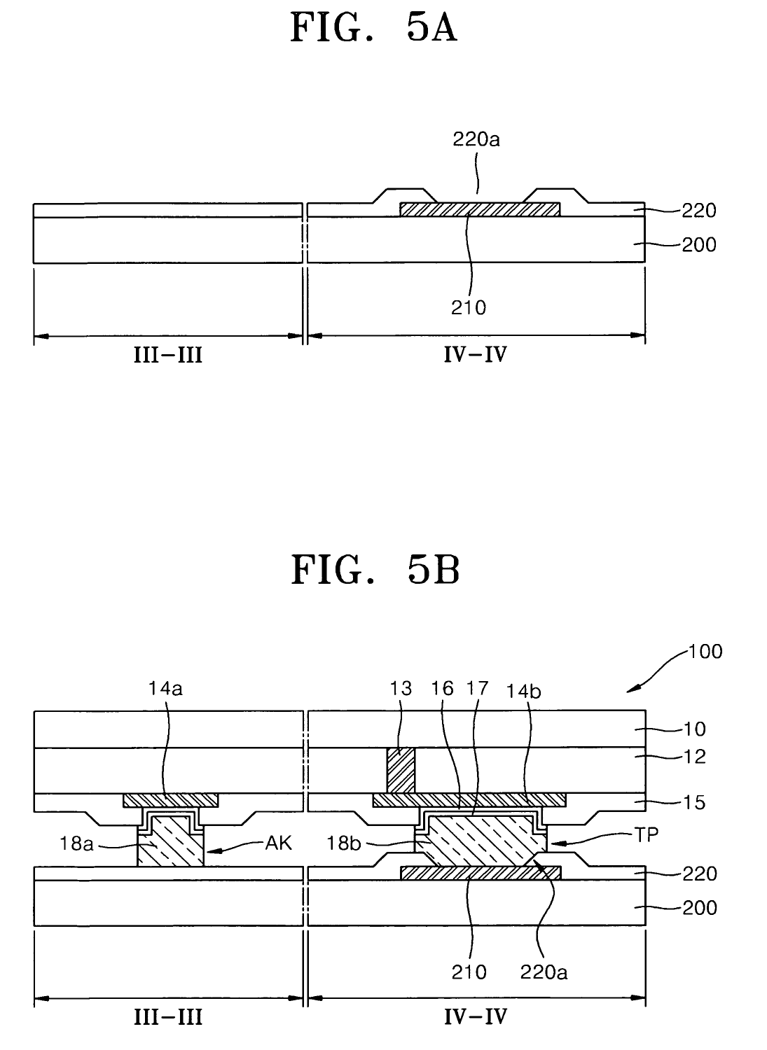

FIGS. 4A and 4B are top views for describing a method of fabricating a semiconductor package according to example embodiments. FIG. 5A is an example cross-sectional view taken along lines III-III and IV-IV of FIG. 4A, and FIG. 5B is an example cross-sectional view taken along lines III-III and IV-IV of FIG. 4b.

Referring to FIGS. 4A and 5A, a wiring substrate 200 may include a bonding pad 210. The wiring substrate 200 may include a display unit D that is electrically connected to the bonding pad 210. In example embodiments, the wiring substrate 200 may be a glass substrate that may transmit light. The display unit D may include a pixel array portion P that displays images. The display unit D may be a liquid crystal display device. In this case, the liquid crystal device may be interposed between the wiring substrate 200 and an upper substrate 201 disposed on the wiring substrate 200.

The bonding pad 210 may be a light-transmitting electrode, for example, indium tin oxide (ITO). A surface insulating film 220, including a groove 220a exposing a part of the bonding pad 210, may be formed on the bonding pad 210.

Referring to FIGS. 4B and 5B, the semiconductor chip 100 may be aligned on the wiring substrate 200, using the metal alignment bump 18a as the alignment mark AK. For example, the portion of the metal alignment bump 18a protruding from the protective film 15 may function as the alignment mark AK. The terminal pad TP of the semiconductor chip 100 may be aligned on the bonding pad 210. In example embodiments, the larger contrast between the metal alignment bump 18a and the protective film 15 may increase the rate of recognizing the alignment mark AK when using alignment equipment, and thus may effectively reduce an alignment error.

The semiconductor chip 100 may be a semiconductor chip described with reference to FIG. 2D. In example embodiments, the semiconductor chip 100 may be disposed and aligned on the wiring substrate 200 so that the terminal pad TP of the semiconductor chip 100, more particularly, the chip metal bump 18b, faces the bonding pad 210. A force may be exerted on the semiconductor chip 100 to connect the chip metal bump 18b on the bonding pad 210. As a result, the bonding pad 210 and the chip metal pad 14b may be electrically connected via the chip metal bump 18b.

Alternately, in example embodiments where the semiconductor chip 100 is a semiconductor chip as described with reference to FIG. 3, the chip metal pad 14b exposed in the aperture 15b, that is, the terminal pad TP, may be electrically connected to the bonding pad 210 using a metal wire (not shown).

According to example embodiments as described above, a relatively large degree of reflection from an metal alignment bump may enhance the contrast between the metal alignment bump and the protective film, thereby improving the rate of recognizing the alignment mark when using the alignment equipment.

According to example embodiments, by forming both the metal alignment bump and the align metal pad from a metal, the adhesion force therebetween may be enhanced. Therefore, the metal alignment bump may not be dislocated from the substrate during shipping and/or packaging processes of the semiconductor chip.

According to example embodiments, by forming the metal alignment bump to extend over the protective film, sidewalls of the metal alignment bump may be located on the protective film and thus the contrast between the metal alignment bump and the protective film at all sidewalls of the metal alignment bump may be achieved.

According to example embodiments, by simultaneously forming the chip metal bump and the metal alignment bump, the metal alignment bump may be formed without an additional process.

While example embodiments have been particularly shown and described, it will be understood by those of ordinary skill in the art that various changes in form and details may be made therein without departing from the spirit and scope as defined by the following claims.

What is claimed is:

1. An alignment mark comprising:
an align metal pad on a substrate and electrically isolated;
a protective film including a first aperture exposing a part of the align metal pad; and
a metal alignment bump on the align metal pad exposed in the first aperture and protruding above the protective film.

2. The alignment mark of claim 1, wherein the metal alignment bump extends over the protective film.

3. The alignment mark of claim 1, further comprising:
a seed metal layer between the align metal pad and the metal alignment bump.

4. A semiconductor chip comprising:
the alignment mark of claim 1, wherein the substrate includes an alignment mark region and a terminal pad region;
the align metal pad on the alignment mark region and a chip metal pad on the terminal pad region;
a protective film including the first aperture and the metal alignment bump and a second aperture exposing a portion of the chip metal pad.

5. The semiconductor chip of claim 4, further comprising:
a chip metal bump on the chip metal pad exposed in the second aperture and protruding above the protective film.

6. The semiconductor chip of claim 4, wherein the metal alignment bump extends over a portion of the protective film.

7. The semiconductor chip of claim 4, further comprising:
a seed metal layer between the align metal pad and the metal alignment bump.

8. A semiconductor package comprising:
the semiconductor chip of claim 4;
a wiring substrate including a bonding pad for mounting the semiconductor chip, wherein the metal alignment bump aligns the semiconductor chip to the wiring substrate.

9. The semiconductor package of claim 8, further comprising:
a display unit electrically connected with the bonding pad and on the wiring substrate.

10. The semiconductor package of claim 8, wherein the semiconductor chip further comprises:
a chip metal bump on the chip metal pad exposed in the second aperture and protruding above the protective film; and
the chip metal bump is between the bonding pad and the chip metal pad.

11. The semiconductor package of claim 8, wherein the metal alignment bump extends over a portion of the protective film.

12. The semiconductor package of claim 8, further comprising:
a seed metal layer between the align metal pad and the metal alignment bump.

13. A method of fabricating an alignment mark, the method comprising:
providing an align metal pad on a substrate;
providing a protective film including a first aperture exposing a part of the align metal pad; and
providing an metal alignment bump on the align metal pad exposed in the first aperture and protruding above the protective film.

14. A method of fabricating a semiconductor chip, the method comprising:
fabricating the alignment mark according to the method of claim 13, wherein the substrate includes an alignment mark region and a terminal pad region, the align metal pad and the metal alignment bump being formed in the alignment mark region, and a chip metal pad formed on the terminal pad region; and
forming a second aperture in the protective film exposing a part of the chip metal pad.

15. The method of claim 14, further comprising:
forming a chip metal bump, simultaneous to forming the metal alignment bump, on the chip metal pad exposed in the second aperture to protrude above the protective film.

16. The method of claim 15, further comprising:
forming a seed metal layer, before forming the metal alignment bump and the chip metal bump, on the align metal pad exposed in the first aperture and on the chip metal pad exposed in the second aperture.

17. The method of claim 16, wherein the metal alignment bump and the chip metal bump are formed using electroplating.

18. The method of claim 14, wherein the metal alignment bump is formed to extend over the protective film.

19. A method of fabricating a semiconductor package, the method comprising:
fabricating the semiconductor chip according to the method of claim 14;
providing a wiring substrate and a bonding pad for mounting the semiconductor chip;
aligning the semiconductor chip to the wiring substrate using the metal alignment bump; and
electrically connecting the bonding pad and the chip metal pad.

20. The method of claim 19, wherein the wiring substrate includes a display unit that is electrically connected to the bonding pad.

21. The method of claim 19, wherein the semiconductor chip further comprises:
a chip metal bump disposed on the chip metal pad exposed in the second aperture and protruding above the protective film;
the semiconductor chip is aligned such that the chip metal bump on the wiring substrate faces the bonding pad; and
the bonding pad and the chip metal pad are electrically connected to each other through the chip metal bump.

22. The method of claim 19, wherein the metal alignment bump extends over the protective film.

23. The method of claim 19, wherein the semiconductor chip further comprises:
a seed metal layer arranged between the align metal pad and the metal alignment bump.
